(19) United States
(12) Patent Application Publication
(10) Pub. No.: US 2010/0000469 A1
(43) Pub. Date: Jan. 7, 2010

(54) DEPOSITION APPARATUS FOR ORGANIC EL AND EVAPORATING APPARATUS

(75) Inventors: Yasushi Yagi, Sendai City (JP); Shingo Watanabe, Sendai City (JP); Yuji Ono, Sendai City (JP); Hiroshi Kaneko, Sendai City (JP); Koyu Hasegawa, Sagamihara-city (JP); Mitsuaki Komino, Tokyo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/494,453

(22) Filed: Jun. 30, 2009

(30) Foreign Application Priority Data
Jul. 1, 2008 (JP) 2008-171979

(51) Int. Cl. C23C 16/54

(52) U.S. Cl. 118/724

(57) ABSTRACT

Provided is a deposition apparatus for organic EL capable of allowing vapor of a film forming material to be vapor deposited on a target object to be uniformly heated. A deposition apparatus, which performs a film forming process by vapor depositing a film forming material on a target object in a depressurized processing chamber, includes an evaporating head having a vapor discharge opening, disposed in the processing chamber, for discharging vapor of the film forming material. Inside the evaporating head, provided is a heater receiving member which is sealed with respect to an inside of the processing chamber, and installed is a communication path which allows the heater receiving member to communicate with an outside of the processing chamber. A power supply line for a heater received in the heater receiving member is disposed in the communication path and extended to the outside of the processing chamber.

### FIELD OF THE INVENTION

The present disclosure relates to a deposition apparatus of organic EL for performing a film forming process by vapor depositing a heated film forming material on a target object to be processed.

### BACKGROUND OF THE INVENTION

Recently, an organic EL device utilizing electroluminescence (EL) has been developed. Since the organic EL device generates almost no heat, it consumes less power as compared to a cathode-ray tube or the like. Further, since the organic EL device is a self-luminescent device, there are some other advantages, for example, a view angle wider than that of a liquid crystal display (LCD), so that progress thereof in the future is expected.

Most typical structure of this organic EL device includes an anode (positive electrode) layer, a light emitting layer and a cathode (negative electrode) layer stacked sequentially on a glass substrate to form a sandwiched shape. In order to bring out light from the light emitting layer, a transparent electrode made of ITO (Indium Tin Oxide) is used as the anode layer on the glass substrate. Such an organic EL device is generally manufactured by forming the light emitting layer and the cathode layer in sequence on the glass substrate on the surface of which the ITO layer (anode layer) is preformed. The light emitting layer may be made of, for example, polycyclic aromatic hydrocarbon, hetero aromatic hydrocarbon, organic metal complex compound, or the like. Further, when necessary, a thin film for enhancing light emitting efficiency may be formed between the anode layer and the light emitting layer, or between the cathode layer and the light emitting layer. Such a thin film can also be formed by a vapor deposition.

A vacuum evaporating apparatus shown in Patent Document 1, for example, is known as an apparatus for forming the light emitting layer of such an organic EL device.

Typically, in a process of forming the light emitting layer of the organic EL device, the inside of a processing chamber is depressurized to a preset pressure. The reason for this is that, when forming the light emitting layer of the organic EL device as described above, if the film formation is performed under the atmospheric pressure to deposit the film forming material on the surface of the substrate by supplying vapor of the film forming material of a high temperature of about 200° C. to 500° C. from an evaporating head, the heat of the vapor of the film forming material would be transmitted through the air inside the processing chamber to various components such as sensors in the processing chamber. As a result, a temperature rise of such components and consequent deterioration of characteristics of the components or damage of the components themselves would be caused. Accordingly, in the process of forming the light emitting layer of the organic EL device, the inside of the processing chamber is depressurized to the preset pressure in order to prevent the escape of the heat from the vapor of the film forming material (heat insulation by vacuum).

Meanwhile, a vapor generating unit for vaporizing the film forming material, a pipe for supplying the vapor of the film forming material to the evaporating head from the vapor generating unit, a control valve for controlling the supply of the vapor of the film forming material, and the like are generally disposed outside the processing chamber for the reason of facilitating replenishment of the film forming material, maintenance, and so forth. However, if the vapor generating unit, the pipe, and the control valve are disposed under the atmospheric pressure, the heat radiation to the air would occur, so that it is difficult to maintain the vapor of the film forming material at a desired temperature while it is being supplied to the evaporating head from the vapor generating unit. Therefore, the vapor generating unit, the pipe, the control valve and the like are also installed in the depressurized space.

Patent Document 1: Japanese Patent Laid-open Publication No. 2000-282219

### BRIEF SUMMARY OF THE INVENTION

However, since a heater for heating vapor of a film forming material in an evaporating head is also placed in a depressurized space, heat of the heater may not be sufficiently transferred to the film forming material due to a heat insulation by vacuum if there is a gap between the heater and a path of the film forming material, however small the gap may be. For this reason, it is difficult to uniformly heat the film forming material, so that the temperature thereof becomes non-uniform.

In view of the foregoing, the present disclosure provides a deposition apparatus for organic EL, capable of allowing the vapor of the film forming material to be uniformly heated by efficiently transferring the heat from the heater to the film forming material.

In accordance with one aspect of the present disclosure, there is provided a deposition apparatus for organic EL which performs a film forming process by vapor depositing a film forming material on a target object to be processed in a depressurized processing chamber, the apparatus including: an evaporating head having a vapor discharge opening, disposed in the processing chamber, for discharging vapor of the film forming material, wherein a heater receiving member, which is sealed with respect to an inside of the processing chamber, is provided inside the evaporating head, and a communication path, which allows the heater receiving member to communicate with an outside of the processing chamber, is installed inside the evaporating head, and a power supply line for a heater received in the heater receiving member is disposed in the communication path and extended to the outside of the processing chamber. By installing the heater under the atmospheric condition, the heat of the heater can be transferred through the air even when a gap is formed between the heater and a surface to be heated.

Desirably, the heater is disposed to surround a path of the vapor of the film forming material and is pressed against an inner wall at a side of the path in the heater receiving member. By installing the heater along the path of the vapor inside the evaporating head through which the vapor finally passes before it is discharged, it is possible to maintain the vapor at a preset temperature when it is discharged. Further, since the heater is pressed toward the path of the vapor, the heat of the heater can be transferred to the path of the vapor efficiently.

A member for pressing the heater may be a disk spring. In this case, it is desirable that the disk spring presses the heater via a pressing plate interposed therebetween.

Further, in accordance with another aspect of the present disclosure, there is provided a deposition apparatus for organic EL which performs a film forming process by vapor depositing a film forming material on a target object to be processed in a depressurized processing chamber, the apparatus including: an evaporating head having a vapor discharge opening, disposed in the processing chamber, for discharging vapor of the film forming material, wherein a heater receiving member, which is sealed with respect to an inside of the processing chamber, is provided inside the evaporating head, and at least one of air, an argon gas and a nitrogen gas is present in the heater receiving member. In this configuration, even when a gap is formed between a heater and a surface to be heated, the heat of the heater can be still transferred through one of the air, an argon gas and the nitrogen gas.

Further, in accordance with still another aspect of the present disclosure, there is provided an evaporating apparatus for performing a film forming process on a target object to be processed by vapor deposition, wherein a processing chamber for performing the film forming process on the target object is disposed adjacent to a vapor generating chamber for vaporizing a film forming material, gas exhaust mechanisms for depressurizing an inside of the processing chamber and an inside of the vapor generating chamber are installed, a vapor discharge opening for discharging vapor of the film forming material is disposed in the processing chamber, a vapor generating unit for vaporizing the film forming material and a control valve for controlling a supply of the vapor of the film forming material are disposed in the vapor generating chamber, an evaporating head, which has a path that is not exposed to outsides of the processing chamber and the vapor generating chamber and supplies the vapor of the film forming material generated by the vapor generating unit to the vapor discharge opening, is installed, a heater receiving member, which is sealed with respect to insides of the vapor generating chamber and the processing chamber, is provided inside the evaporating head, and a communication path, which allows the heater receiving member to communicate with the outsides of the vapor generating chamber and the processing chamber, is installed inside the evaporating head, and a power supply line for a heater received in the heater receiving member is disposed in the communication path and extended to the outsides of the vapor generating chamber and the processing chamber.

Further, in accordance with still another aspect of the present disclosure, there is provided an evaporating apparatus for performing a film forming process on a target object to be processed by vapor deposition, wherein a processing chamber for performing the film forming process on the target object is disposed adjacent to a vapor generating chamber for vaporizing a film forming material, gas exhaust mechanisms for depressurizing an inside of the processing chamber and an inside of the vapor generating chamber are installed, a vapor discharge opening for discharging vapor of the film forming material is disposed in the processing chamber, a vapor generating unit for vaporizing the film forming material and a control valve for controlling a supply of the vapor of the film forming material are disposed in the vapor generating chamber, an evaporating head, which has a path that is not exposed to outsides of the processing chamber and the vapor generating chamber and supplies the vapor of the film forming material generated by the vapor generating unit to the vapor discharge opening, is installed, a heater receiving member, which is sealed with respect to insides of the vapor generating chamber and the processing chamber, is provided inside the evaporating head, and at least one of air, an argon gas and a nitrogen gas is present in the heater receiving member.

In accordance with the present disclosure, the heat of the heater can be transferred to the film forming material efficiently, and a vaporization rate of the film forming material discharged into the processing chamber and the temperature of the vapor of the film forming material can be maintained to be uniform.

### BRIEF DESCRIPTION OF THE DRAWINGS

The disclosure may best be understood by reference to the following description taken in conjunction with the following figures:

FIG. 1 is a diagram for describing an organic EL device;

FIG. 2 is a diagram illustrating a film formation system;

FIG. 3 is a cross sectional view schematically illustrating a configuration of an evaporating apparatus in accordance with an embodiment of the present disclosure;

FIG. 4 is a perspective view of an evaporating unit;

FIG. 5 is a circuit diagram of the evaporating unit;

FIG. 6 is a perspective view illustrating an installation state of an evaporating head;

FIG. 7 shows a cross sectional view illustrating an installation state of a heater in a heater receiving member of the evaporating head, and an enlarged view of a part thereof;

FIG. 8 is a perspective view illustrating an example of a disk spring used in FIG. 7;

FIG. 9 is a perspective view illustrating the evaporating unit installed with another example of communication paths;

FIG. 10 is a perspective view illustrating an installation state of another example of the evaporating unit;

FIG. 11 shows a front view and a plane view of a test object of an experiment example; and

FIGS. 12A to 12C are cross sectional views illustrating installation states of a heater in the experiment example, wherein FIG. 12A shows an installation method in accordance with the present disclosure; FIG. 12B illustrates a case of installing spacers having a thickness of about 0.2 mm; and FIG. 12C shows a case in accordance with a conventional method.

### DETAILED DESCRIPTION OF THE INVENTION

Hereinafter, an embodiment of the present disclosure will be described in detail with reference to the accompanying drawings. Like reference numerals denote like parts through the whole document, and redundant description thereof will be omitted.

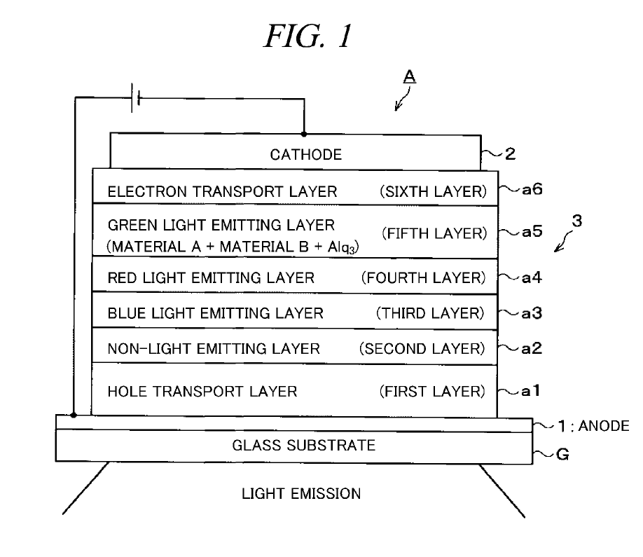

FIG. 1 provides a diagram for describing an organic EL device A manufactured in accordance with the embodiment of the present disclosure. The most typical structure of this organic EL device A is a sandwich structure in which a light emitting layer 3 is interposed between an anode 1 and a cathode 2. The anode 1 is formed on a glass substrate G which is a target object to be processed. A transparent electrode made of, e.g., ITO (Indium Tin Oxide) capable of transmitting light of the light emitting layer 3 is used as the anode 1.

An organic layer serving as the light emitting layer 3 may be single-layered or multi-layered. In FIG. 1, it is a 6-layered structure having a first layer a1 to a sixth layer a6, layered on top of each other. The first layer a1 is a hole transport layer; the second layer a2 is a non-light emitting layer (electron blocking layer); the third layer a3 is a blue light emitting layer; the fourth layer a4 is a red light emitting layer; the fifth layer a5 is a green light emitting layer; and the sixth layer a6 is an electron transport layer. Such an organic EL device A is manufactured through the processes of forming the light emitting layer 3 (i.e., the first layer al to the sixth layer a6) on the anode 1 on the surface of the glass substrate G in sequence; forming the cathode 2 made of Ag, an Mg/Ag alloy or the like, after interposing a work function adjustment layer (not shown) therebetween; and finally sealing the entire structure with a nitride film (not shown), as will be explained later.

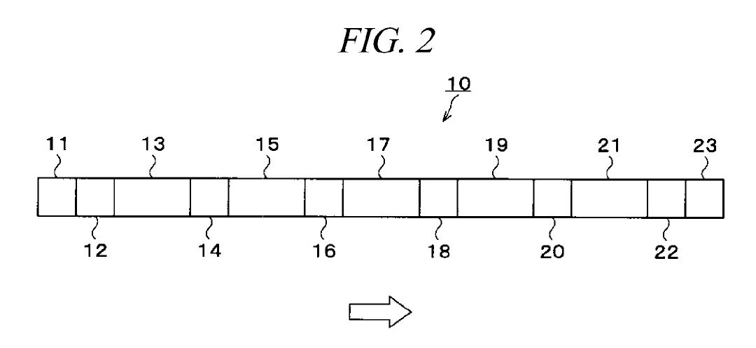

FIG. 2 illustrates a diagram describing a film formation system 10 for manufacturing the organic EL device A. The film formation system 10 has a configuration in which a loader 11, a transfer chamber 12, an evaporating apparatus 13 for the light emitting layer 3, a transfer chamber 14, a film forming apparatus 15 for the work function adjustment layer, a transfer chamber 16, an etching apparatus 17, a transfer chamber 18, a sputtering apparatus 19, a transfer chamber 20, a CVD apparatus 21, a transfer chamber 22 and an unloader 23 are sequentially arranged in series along a transfer direction (right direction in FIG. 2) of the substrate G. The loader 11 is an apparatus for loading the substrate G into the film formation system 10. The transfer chambers 12, 14, 16, 18, 20 and 22 are apparatuses for transferring the substrate G between the respective processing apparatuses. The unloader 23 is an apparatus for unloading the substrate G from the film formation system 10.

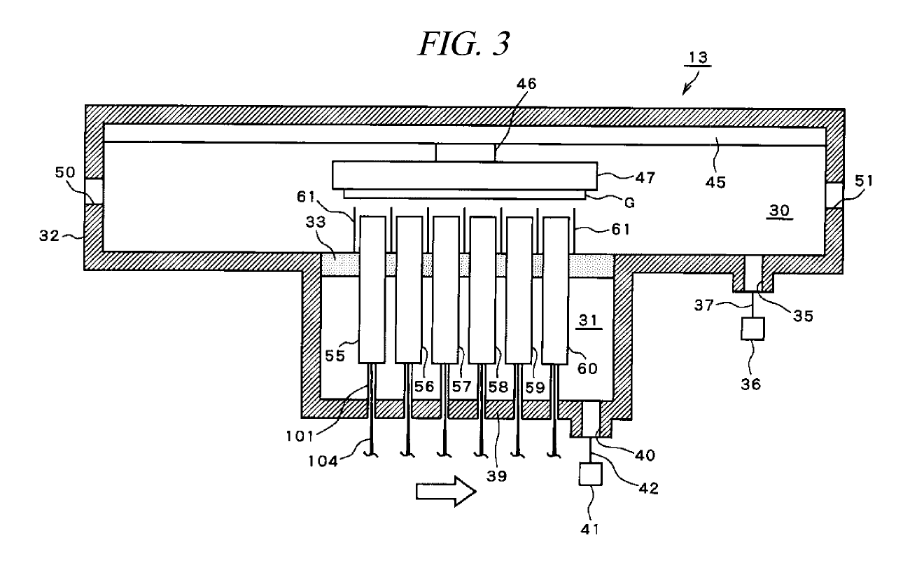

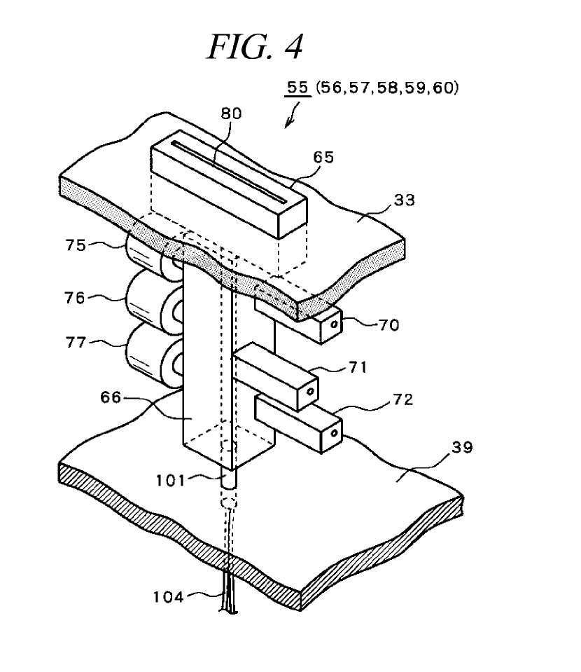

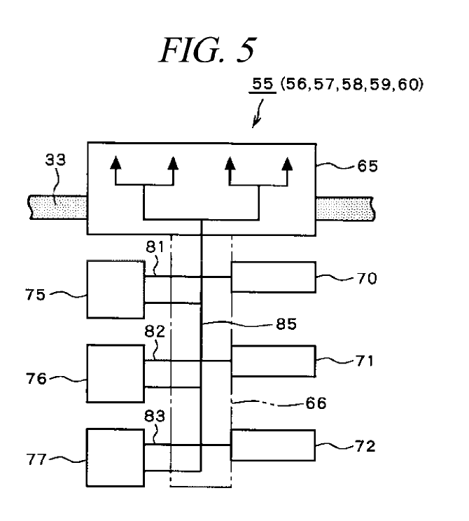

Hereinafter, the evaporating apparatus 13 in accordance with the embodiment of the present disclosure will be described in further detail. FIG. 3 is a cross sectional view schematically illustrating the configuration of the evaporating apparatus 13; FIG. 4 depicts a perspective view showing an evaporating unit 55 (56, 57, 58, 59 and 60) incorporated in the evaporating apparatus 13; and FIG. 5 sets forth a circuit diagram of the evaporating unit 55 (56, 57, 58, 59 and 60).

The evaporating apparatus 13 has a configuration in which a processing chamber 30 for performing the film formation on the substrate G therein and a vapor generating chamber 31 for vaporizing a film forming material therein are vertically arranged adjacent to each other. The processing chamber 30 and the vapor generating chamber 31 are formed inside a chamber main body 32 made of aluminum, stainless steel, or the like, and the processing chamber 30 and the vapor generating chamber 31 are divided by a partition wall 33 made of a thermal insulator and provided therebetween.

A gas exhaust hole 35 is opened in a bottom surface of the processing chamber 30, and a vacuum pump 36, which serves as a gas exhaust mechanism and is disposed outside the chamber main body 32, is connected to the gas exhaust hole 35 via a gas exhaust pipe 37. The inside of the processing chamber 30 is depressurized to a preset pressure level by the operation of the vacuum pump 36.

Likewise, a gas exhaust hole 40 is opened in a bottom surface 39 of the vapor generating chamber 31, and a vacuum pump 41, which serves as a gas exhaust unit and is disposed outside the chamber main body 32, is connected to the gas exhaust hole 40 via a gas exhaust pipe 42. The inside of the vapor generating chamber 31 is depressurized to a predetermined pressure level by the operation of the vacuum pump 41.

Installed at the top of the processing chamber 30 are a guide member 45 and a supporting member 46 moving along the guide member 45 by an appropriate driving source (not shown). A substrate holding unit 47 such as an electrostatic chuck or the like is installed at the supporting member 46, and the substrate G, which is the target of the film formation, is horizontally held on the bottom surface of the substrate holding unit 47.

A loading port 50 and an unloading port 51 are provided at side surfaces of the processing chamber 30. In the evaporating apparatus 13, the substrate G loaded from the loading port 50 is held by the substrate holding unit 47 and is transferred to the right side in the processing chamber 30 in FIG. 3 to be unloaded from the unloading port 51.

At the partition wall 33 dividing the processing chamber 30 and the vapor generating chamber 31, arranged along the transfer direction of the substrate G are six evaporating units 55, 56, 57, 58, 59 and 60 for supplying vapors of film forming materials. These evaporating units 55 to 60 include the first evaporating unit 55 for depositing the hole transport layer; the second evaporating unit 56 for depositing the non-light emitting layer; the third evaporating unit 57 for depositing the blue light emitting layer; the fourth evaporating unit 58 for depositing the red light emitting layer; the fifth evaporating unit 59 for depositing the green light emitting layer; and the sixth evaporating unit 60 for depositing the electron transport layer, and they deposit the vapors of the film forming materials in sequence onto the bottom surface of the substrate G while it is being transferred and being held by the substrate holding unit 47. Further, vapor division walls 61 are arranged between the respective evaporating units 55 to 60, so that the vapors of the film forming materials supplied from the respective evaporating units 55 to 60 are allowed to be deposited on the bottom surface of the substrate G in sequence without being mixed with each other.

Since all the evaporating units 55 to 60 have the same configuration, only the configuration of the first evaporating unit 55 will be explained as a representative example. As illustrated in FIG. 4, the evaporating unit 55 has a configuration in which a pipe case (transport path) 66 is installed at the bottom side of an evaporating head 65, and three vapor generating units 70, 71 and 72 are disposed at one side of the pipe case 66 while three control valves 75, 76 and 77 are disposed at the opposite side.

A vapor discharge opening 80 for discharging the vapors of the film forming materials for the light emitting layer 3 of the organic EL device A is formed at the top surface of the evaporating head 65. The vapor discharge opening 80 is provided in a slit shape along a direction perpendicular to the transfer direction of the substrate G and has a length equal to or slightly longer than the width of the substrate G. By transferring the substrate G by means of the substrate holding unit 47 while discharging the vapors of the film forming materials from this slit-shaped vapor discharge opening 80, a film can be formed on the entire bottom surface of the substrate G.

The evaporating head 65 is supported by the partition wall 33 for dividing the processing chamber 30 and the vapor generating chamber 31 while its top surface provided with the vapor discharge opening 80 is exposed to the inside of the processing chamber 30. The bottom surface of the evaporating head 65 is exposed to the inside of the vapor generating chamber 31. The pipe case 66 installed at the bottom surface of the evaporating head 65, the vapor generating units 70 to 72 installed at the pipe case 66 and the control valves 75 to 77 installed at the pipe case 66 are all located within the vapor generating chamber 31. Further, a communication path 101 passes through the bottom surface 39 from a bottom portion of the pipe case 66 to the outside of the processing chamber 30.

As depicted in FIG. 5, the three vapor generating units 70, 71 and 72 and the three control valves 75, 76 and 77 are in correspondence relationship. To elaborate, the control valve 75 controls the supply of the vapor of the film forming material generated from the vapor generating unit 70; the control valve 76 controls the supply of the vapor of the film forming material generated from the vapor generating unit 71; and the control valve 77 controls the supply of the vapor of the film forming material generated from the vapor generating unit 72. Installed inside the pipe case 66 are branch pipes 81, 82 and 83 for connecting the vapor generating units 70 to 72 with the control valves 75 to 77, respectively, and a joint pipe 85 for joining the vapors of the film forming materials generated from the respective vapor generating units 70 to 72 via the respective control valves 75 to 77 and supplying them to the evaporating head 65. All the vapor generating units 70 to 72 have the same configuration, and each of them accommodates therein the film forming material (deposition material) for the light emitting layer 3 of the organic EL device A and has a plurality of heaters on lateral sides thereof for evaporating the film forming material.

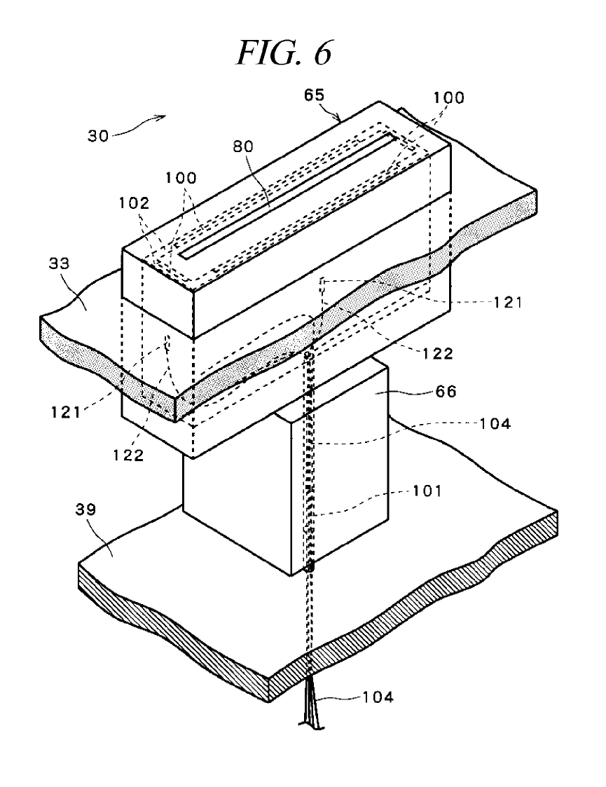

At the evaporating head 65, a heater 100 is installed to surround the vicinity of a path for the vapor of the film forming material, as shown in FIG. 6. Since the heater 100 is installed along the entire lateral side of the path for the vapor, it is possible to reduce temperature non-uniformity of the vapor passing through the inside of the evaporating head 65 and heat the vapor uniformly.

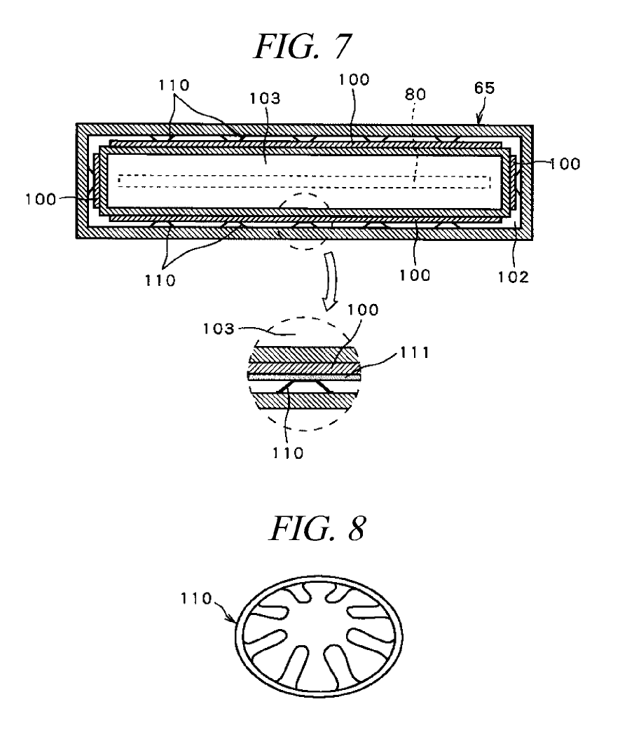

FIG. 7 shows a diagram illustrating a layout example of the heater 100 within a heater receiving member 102 and an enlarged view of the inside of a dashed-lined circle. As illustrated in FIG. 7, the heater 100 is installed inside the heater receiving member 102. The heater 100 is pressed against the heater receiving member 102's inner surface facing a path 103 for the vapor of the film forming material. For example, a disk spring 110 as shown in FIG. 8 is used as a member for pressing the heater 100, and plural disk springs 110 may be arranged at certain intervals. Further, it is desirable to dispose a pressing plate 111, as illustrated in the enlarged view of FIG. 7, between the disk spring 110 and the heater 100 such that a pressing force of the disk spring 110 is uniformly transferred to the entire surface of the heater 100. In this way, as the heater 100 is pressed toward the path 103, heat can be efficiently and uniformly transferred to the vapor of the film forming material which is passing through the inside of the evaporating head 65. As a result, a temperature control can be facilitated, so that the temperature of the vapor can be stabilized, and a stable vapor deposition process can be implemented.

Further, as illustrated in FIG. 4, the communication path 101 accommodating therein a power supply line 104 for supplying power to the heater 100 is communicated to the outside of the processing chamber 30. Through the communication path 101, the air is introduced into the heater receiving member 102, and the heater 100 is disposed under the atmospheric condition. Thus, even if there is formed a gap between the heater 100 and the lateral surface of the heater receiving member 102, the heat can still be transferred from the heater 100 to the path 103 through the air, so that the heat can be transferred uniformly.

Moreover, as depicted in FIG. 6, by installing a temperature measurement device such as a thermocouple 121 or the like in the heater receiving member 102, the temperature of the heater 100 can be measured, and a proper temperature control can be performed by the feedback of temperature data. A connection line 122 of the thermocouple 121 and the power supply line 104 for supplying the power to the heater 100 are extended to the outside of the processing chamber 30 through the communication path 101.

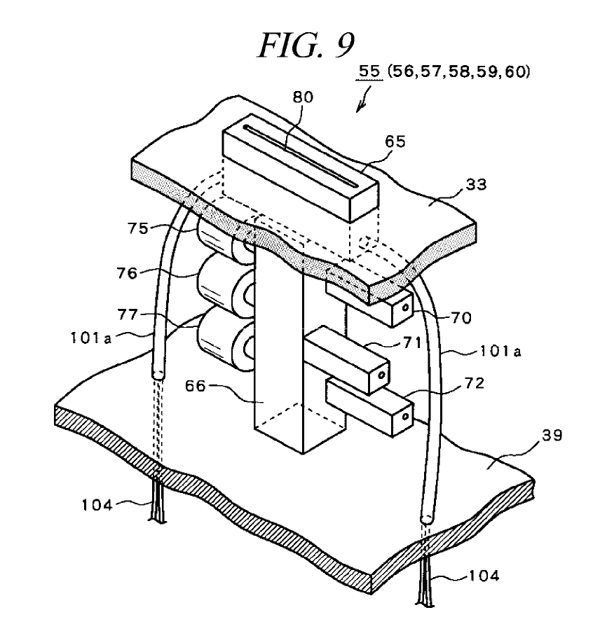

In addition, FIG. 9 illustrates the evaporating unit 55 installed with another example of communication paths 101a. As shown in FIG. 9, the communication paths 101a extend from two lower lateral sides of the evaporating head 65 and pass through the bottom surface 39 of the vapor generating chamber 31, such that the inside of the evaporating head 65 can be communicated with the outside of the vapor generating chamber 31. Each of the communication paths 101a may have, for example, a bellows shape, so that it can be transformed flexibly, and may be made of stainless steel or the like. Like the above-described communication path 101 in FIG. 4, the power supply lines 104 to the heater 100 pass through the inside of the communication paths 101a of FIG. 9 and extend to the outside of the processing chamber 30.

Furthermore, as shown in FIG. 10, it may be also possible to form the heater receiving member 102 in the evaporating head 65 to have a sealed space therein and fill the inside thereof with an argon gas, a nitrogen gas or the like, so that a pressure therein becomes, e.g., several tens of Torr. In such a case, the heat from the heater 100 can be transferred through these gases. Further, the power supply line 104 to the heater 104 passes through, e.g., the inside of the vapor generating chamber 31 and extends to the outside of the processing chamber 30.

Besides, the film forming apparatus 15 for the work function adjustment layer as shown in FIG. 2 is configured to form the work function adjustment layer on the surface of the substrate G by vapor deposition. The etching apparatus 17 is configured to etch each formed layer. The sputtering apparatus 19 is configured to form the cathode 2 by sputtering an electrode material such as Ag or the like. The CVD apparatus 21 seals the organic EL device A by forming a sealing film made of a nitride film or the like by CVD or the like.

In the film formation system 10 configured as described above, a substrate G loaded through the loader 11 is first loaded into the evaporating apparatus 13 through the transfer chamber 12. Here, the anode 1 made of, e.g., ITO is previously formed on the surface of the substrate G in a preset pattern.

In the evaporating apparatus 13, the substrate G is held by the substrate holding unit 47 while the substrate surface (film formation surface) faces downward. Further, before the substrate G is loaded into the evaporating apparatus 13, the insides of the processing chamber 30 and the vapor generating chamber 31 of the evaporating apparatus 13 are previously depressurized to preset pressure levels by the vacuum pumps 36 and 41.

Furthermore, in the depressurized vapor generating chamber 31, the vapors of the film forming materials vaporized in the respective vapor generating units 70 to 72 are joined in the joint pipe 85 in a certain combination by the opening/closing operations of the control valves 75 to 77, and supplied to the evaporating head 65. Then, the vapors of the film forming materials supplied to the evaporating head 65 are discharged from the vapor discharge opening 80 provided at the top surface of the evaporating head 65 in the processing chamber 30 while the temperature of the vapors is controlled to be uniform by the heater 100.

Meanwhile, in the depressurized processing chamber 30, the substrate G held by the substrate holding unit 47 is transferred to the right of FIG. 3. While the substrate G is moving, the vapors of the film forming materials are supplied from the vapor discharge openings 80 of the top surfaces of the evaporating heads 65, so that the light emitting layer 3 is formed/deposited on the surface of the substrate G. By supplying the vapors whose temperatures are uniform, a high-quality film forming process can be carried out.

The substrate G on which the light emitting layer 3 is formed in the evaporating apparatus 13 is loaded into the film forming apparatus 15 through the transfer chamber 14. In the film forming apparatus 15, the work function adjustment layer is formed on the surface of the substrate G.

Subsequently, the substrate G is loaded into the etching apparatus 17 through the transfer chamber 16, and each formed film is shaped therein. Then, the substrate G is loaded into the sputtering apparatus 19 through the transfer chamber 18, and the cathode 2 is formed thereon. Thereafter, the substrate G is loaded into the CVD apparatus 21 through the transfer chamber 20, and sealing of the organic EL device A is performed therein. The organic EL device A thus manufactured is unloaded from the film formation system 10 through the transfer chamber 22 and the unloader 23.

The above description of the present invention is provided for the purpose of illustration, and do not limit the present invention. It would be understood by those skilled in the art that all modifications and embodiments conceived from the meaning and scope of the claims and their equivalents are included in the scope of the present invention. For example, the substrate G to be processed may be of various types such as a glass substrate, a silicon substrate, a rectangular or annularly shaped substrate. Furthermore, the present disclosure can also be applied to a target object to be processed other than the substrate.

FIG. 2 illustrates the film formation system 10 having the configuration in which the loader 11, the transfer chamber 12, the evaporating apparatus 13 for the light emitting layer 3, the transfer chamber 14, the film forming apparatus 15 for the work function adjustment layer, the transfer chamber 16, the etching apparatus 17, the transfer chamber 18, the sputtering apparatus 19, the transfer chamber 20, the CVD apparatus 21, the transfer chamber 22 and the unloader 23 are sequentially arranged in series along the transfer direction of the substrate G. However, it is not limited thereto and the number and arrangement of each processing apparatus may be varied.

Moreover, the materials discharged from the evaporating head 65 of each of the evaporating units 55 to 60 may be the same or different from each other. Further, the number of the evaporating units is not limited to six, but can be varied. In addition, the number of the vapor generating units or the control valves installed in the evaporating unit can also be varied.

### EXPERIMENTAL EXAMPLE 1

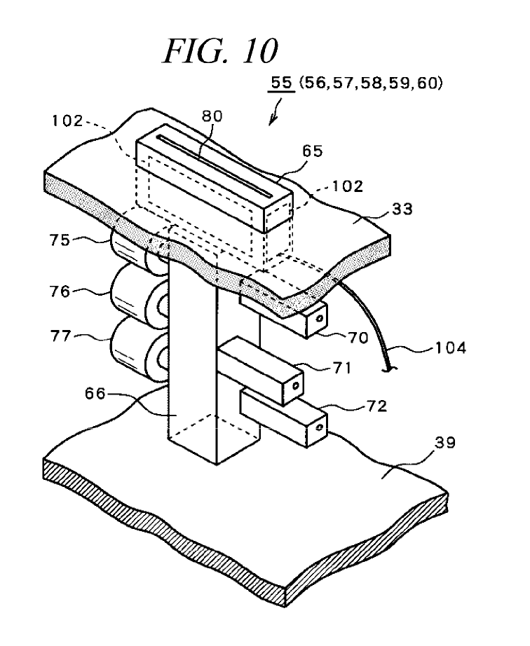

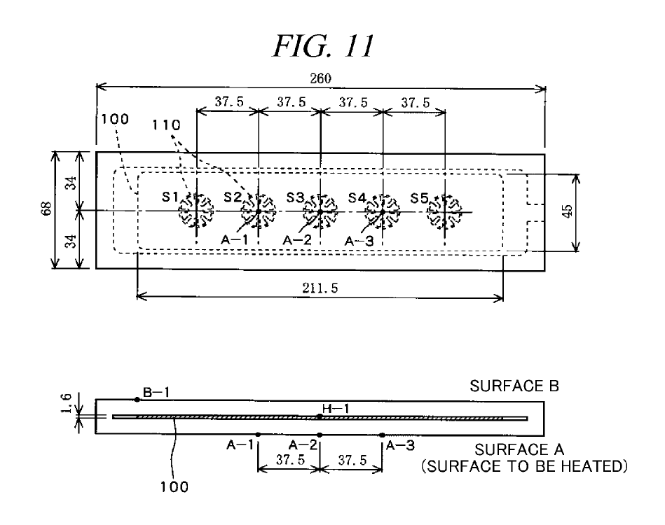

As illustrated in FIG. 11, a mica heater having a size of 45 mm×211.5 mm was accommodated in a housing having a size of 68 mm×260 mm. Then, measured were temperatures of points A-1, A-2 and A-3 at a surface A which is a surface to be heated (a surface of a path of vapor) and a temperature of a point H-1 which is a central point of the heater itself and a temperature of a point B-1 at a rear surface (surface B) of an end portion of the heater. The heater was a mica heater, and a thickness of the heater was 1.5 mm. A thickness of a heater receiving member was 1.6 mm having a clearance of 0.1 mm with respect to the thickness of the heater.

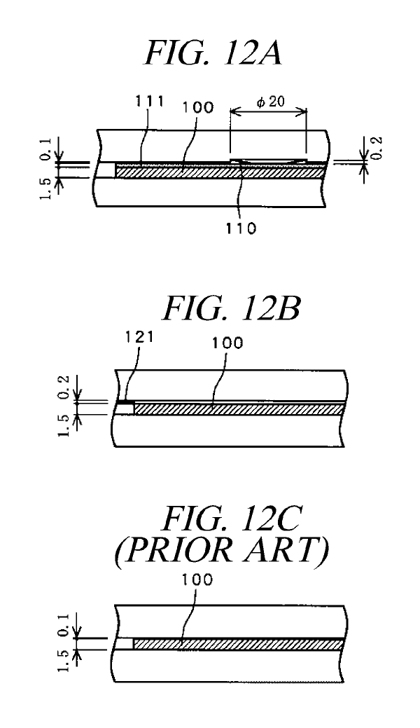

As for an installation method of the heater in accordance with an example of the present disclosure as illustrated in FIG. 12A, a rear surface of a heater 100 was firmly pressed toward a surface (surface A) to be heated by a disk spring 110 via a pressing plate 111 interposed therebetween. The experiment was conducted for two cases where a thickness of the pressing plate 111 was set to be 0.2 mm and 0.3 mm. No. 3 indicates a case in which the pressing plate 111 has a thickness of 0.2 mm and the disk springs 110 are disposed at three positions S1, S3 and S5 of FIG. 11, and No. 4 indicates a case in which the pressing plate 111 has a thickness of 0.2 mm and the disk springs 110 are disposed at five positions S1 to S5. No. 5 indicates a case in which a thickness of the pressing plate 111 is 0.3 mm and the disk springs 110 are disposed at five positions, like in No. 4. Furthermore, to prevent position deviation of the disk springs 110, cutoff portions having a depth of 0.2 mm were formed in the housing at positions where the disk springs 110 are disposed. The shape of the employed disk springs 110 is the same as illustrated in FIG. 8.

As a comparative example, No. 1 indicates a case in which spacers 121 having a thickness of 0.2 mm are disposed at two ends of the heater 100, thus providing a gap of 0.2 mm, as illustrated in FIG. 12B. Further, as a conventional method, No. 2 indicates a case where the heater 100 is accommodated in the receiving member having a thickness larger than that of the heater by 0.1 mm, i.e., it has a gap of 0.1 mm, as shown in FIG. 12C. For both cases of a horizontal layout in which a plane side of the housing is positioned horizontally and a vertical layout in which the plane side of the housing is positioned vertically, a heater was heated until the temperature of the point A-1 reached 450° C., and the temperature of each point was measured. Measurement results are provided in Table 1.

TABLE 1

| | | | | | | | |
|---|---|---|---|---|---|---|---|
| | | | | | ΔT | | |
| No. | Installation state | A-1 | A-2 | A-3 | (Tmax − Tmin) | B-1 | H-1 |

Average temperature in horizontal layout (° C.)

| | | | | | | | |
|---|---|---|---|---|---|---|---|
| \textcircled{1} | Presence of gap of 0.2 mm | 450.0° C. | 465.3° C. | 453.9° C. | 15.3° C. | 326.3° C. | 697.6° C. |
| \textcircled{2} | No spring | 450.0° C. | 462.4° C. | 449.5° C. | 12.4° C. | 322.2° C. | 626.5° C. |
| | (Conventional design) | | | | | | |
| \textcircled{3} | Three disk springs/ | 450.0° C. | 462.4° C. | 449.9° C. | 12.4° C. | 316.0° C. | 629.9° C. |
| | Pressing plate of 0.2 mm | | | | | | |
| \textcircled{4} | Five disk springs/ | 450.0° C. | 461.9° C. | 449.9° C. | 11.9° C. | 315.5° C. | 651.7° C. |
| | Pressing plate of 0.2 mm | | | | | | |
| \textcircled{5} | Five disk springs/ | 450.0° C. | 460.9° C. | 454.1° C. | 10.9° C. | 327.1° C. | 648.3° C. |
| | Pressing plate of 0.3 mm | | | | | | |

Average temperature in vertical layout (° C.)

| | | | | | | | |
|---|---|---|---|---|---|---|---|
| \textcircled{1} | Presence of gap of 0.2 mm | 450.0° C. | 464.5° C. | 452.0° C. | 14.5° C. | 323.7° C. | 739.1° C. |
| \textcircled{2} | No spring | 450.0° C. | 458.3° C. | 446.7° C. | 11.6° C. | 318.9° C. | 643.7° C. |
| | (Conventional design) | | | | | | |
| \textcircled{3} | Three disk springs/ | 450.0° C. | 458.1° C. | 447.4° C. | 10.7° C. | 315.6° C. | 647.0° C. |
| | Pressing plate of 0.2 mm | | | | | | |
| \textcircled{4} | Five disk springs/ | 450.0° C. | 461.7° C. | 449.9° C. | 11.7° C. | 311.1° C. | 651.1° C. |
| | Pressing plate of 0.2 mm | | | | | | |
| \textcircled{5} | Five disk springs/ | 450.0° C. | 458.6° C. | 452.4° C. | 8.6° C. | 329.5° C. | 666.7° C. |
| | Pressing plate of 0.3 mm | | | | | | |

As can be seen from Table 1, in both the horizontal layout and the vertical layout, by firmly pressing the heater 100 toward the surface to be heated by using the disk springs 110, non-uniformity of the temperature (temperature difference ΔT) of the surface (surface A) to be heated was reduced. Non-uniformity of the temperature was more reduced when using the pressing plate 111 of 0.3 mm than using the pressing plate 111 of 0.2 mm. When the temperature of the point A-1 reaches 450° C., the temperature of the heater itself (temperature of the point H-1) was the highest in case of No. 1 having a large gap size. In case of using the pressing plate 111 of 0.3 mm, though the temperature of the point H-1 was observed to increase slightly, it allowed non-uniformity of the temperature to be reduced, so that it is effective for stabilizing the temperature of the vapors of the film forming materials.

### INDUSTRIAL APPLICABILITY

The present disclosure may be applied to, e.g., a field of manufacturing an organic EL device.

What is claimed is:

1. A deposition apparatus for organic EL which performs a film forming process by vapor depositing a film forming material on a target object to be processed in a depressurized processing chamber, the apparatus comprising:
an evaporating head having a vapor discharge opening, disposed in the processing chamber, for discharging vapor of the film forming material,
wherein a heater receiving member, which is sealed with respect to an inside of the processing chamber, is provided inside the evaporating head, and a communication path, which allows the heater receiving member to communicate with an outside of the processing chamber, is installed inside the evaporating head, and
a power supply line for a heater received in the heater receiving member is disposed in the communication path and extended to the outside of the processing chamber.

2. The deposition apparatus for organic EL of claim 1, wherein the heater is disposed to surround a path of the vapor of the film forming material and is pressed against an inner wall at a side of the path in the heater receiving member.

3. The deposition apparatus for organic EL of claim 2, wherein a member for pressing the heater is a disk spring.

4. The deposition apparatus for organic EL of claim 3, wherein the disk spring presses the heater via a pressing plate interposed therebetween.

5. A deposition apparatus for organic EL which performs a film forming process by vapor depositing a film forming material on a target object to be processed in a depressurized processing chamber, the apparatus comprising:
an evaporating head having a vapor discharge opening, disposed in the processing chamber, for discharging vapor of the film forming material,
wherein a heater receiving member, which is sealed with respect to an inside of the processing chamber, is provided inside the evaporating head, and
at least one of air, an argon gas and a nitrogen gas is present in the heater receiving member.

6. An evaporating apparatus for performing a film forming process on a target object to be processed by vapor deposition,
wherein a processing chamber for performing the film forming process on the target object is disposed adjacent to a vapor generating chamber for vaporizing a film forming material,
gas exhaust mechanisms for depressurizing an inside of the processing chamber and an inside of the vapor generating chamber are installed,
a vapor discharge opening for discharging vapor of the film forming material is disposed in the processing chamber,
a vapor generating unit for vaporizing the film forming material and a control valve for controlling a supply of the vapor of the film forming material are disposed in the vapor generating chamber,
an evaporating head, which has a path that is not exposed to outsides of the processing chamber and the vapor generating chamber and supplies the vapor of the film forming material generated by the vapor generating unit to the vapor discharge opening, is installed,
a heater receiving member, which is sealed with respect to insides of the vapor generating chamber and the processing chamber, is provided inside the evaporating head, and a communication path, which allows the heater receiving member to communicate with the outsides of the vapor generating chamber and the processing chamber, is installed inside the evaporating head, and
a power supply line for a heater received in the heater receiving member is disposed in the communication path and extended to the outsides of the vapor generating chamber and the processing chamber.
